(19) United States
(12) Patent Application Publication
(10) Pub. No.: US 2024/0213392 A1
(43) Pub. Date: Jun. 27, 2024

(54) ON-CHIP SPECTROMETER WITH TUNABLE PHOTODETECTION LAYER

(71) Applicants: Bar-Ilan University, Ramat Gan (IL); Yale University, New Haven, CT (US)

(72) Inventors: Doron NAVEH, Petah-Tikva (IL); Fengnian XIA, Orange, CT (US); Shaofan YUAN, New Haven, CT (US)

(21) Appl. No.: 18/557,008

(22) PCT Filed: Apr. 28, 2022
(86) PCT No.: PCT/US2022/026673

§ 371 Date: Oct. 24, 2023

Related U.S. Application Data
(60) Provisional application No. 63/180,664, filed on Apr. 28, 2021.

(51) Int. Cl. H01L 31/113; G01J 3/28; H01L 31/0232; H01L 31/0352

(52) U.S. Cl. CPC H01L 31/1136; G01J 3/28; H01L 31/02327; H01L 31/035236

(57) ABSTRACT

Apparatuses and methods are provided for reconstructing a spectrum of an incident source. An example apparatus includes a photodetection layer, a voltage source, and a voltage drain. In some embodiments, the example apparatus further includes one or more gate electrodes. The photodetection layer includes one or more photodetection materials and is configured to generate a photoresponse vector in response to an incident source and/or gate electrodes. The voltage source and voltage drain are electrically connected to the photodetection layer and are configured to measure the photoresponse vector generated by the photodetection layer. The spectrum of the unknown incidence light can be reconstructed by using the photoresponse vector and the pre-measured response matrix.

### CROSS REFERENCE TO RELATED APPLICATIONS

This application claims priority to U.S. Provisional Application No. 63/180,664, filed Apr. 28, 2021, the contents of which application are incorporated by reference herein in its entirety.

### FEDERALLY SPONSORED RESEARCH OR DEVELOPMENT

This invention was made with government support under FA9550-19-1-0109 awarded by the United States Air Force Office of Scientific Research. The government has certain rights in the invention.

### TECHNOLOGICAL FIELD

Embodiments of the present disclosure relate generally to spectrometer devices, and, more particularly, to on-chip spectrometer devices with a tunable photodetection layer.

### BACKGROUND

Spectrometers are instruments used to separate and measure spectral components of physical phenomenon, such as the intensity of incident light over specific portions of the electromagnetic spectrum. Traditionally, such spectrometers include mechanically movable components, such as optical gratings as used in visible and near-infrared spectrometers and/or Michaelson interferometers as used in Fourier Transform Infrared (FTIR) spectrometers. These mechanically movable components often result in bulky devices with large device footprints. Through applied effort, ingenuity, and innovation, many of the problems associated with these devices have been solved by developing solutions that are included in embodiments of the present disclosure, many examples of which are described in detail herein.

### BRIEF SUMMARY

Embodiments of the present disclosure address the above by providing an apparatus which may serve as a spectrometer and further, may serve as an “on-chip” spectrometer. The on-chip spectrometer may be fabricated upon a small chip (e.g., glass, silicon, or plastic wafer) such that spectrometer has a smaller device footprint than traditional spectrometers. Furthermore, the spectrometer may include a single photodetection layer that is capable of generating an electrical signal (e.g., voltage or current) in response to incident source (e.g., light). the output signal of the spectrometer may further be structured in matrix representation, such as in a photoresponse matrix, that may be defined by input voltage values. the photoresponse matrix is determined based at least in part on the photoresponse of the photodetection layer, generated in response to one or more applied electrical voltage biases.

An apparatus of the present disclosure may include a photodetection layer that includes one or more photodetection materials is configured to generate a photoresponse in response to an incident source. Such an embodiment may further include a voltage source electrically connected with the photodetection layer, and a voltage drain electrically connected with the voltage source and the photodetection layer. The voltage drain and the voltage source may be configured to measure the photoresponse generated by the photodetection layer. A photoresponse matrix associated with the apparatus may be configured with values determined based at least in part on the photoresponse of the photodetection layer generated in response to one or more applied electrical voltage biases to tune the photodetection layer properties.

In some embodiments, the voltage source and voltage drain each include a conductive metal.

In some embodiments, the apparatus may further include a base substrate, wherein the voltage drain is in positioned upon a top side of the base substrate, the photodetection layer is positioned upon a top side of the voltage drain, and the voltage source is positioned upon a top side of the voltage source. In such an embodiment, the apparatus may further include a plurality of quantum well structures defined by the photodetection layer.

In some further embodiments, the plurality of quantum well structures may further include plurality of quantum well groups each of which is associated with a peak absorption wavelength.

In some further embodiments, the base substrate may include a group III-group IV material, silicon, or germanium.

In some still further embodiments, the base substrate may be configured to epitaxially grow the plurality of quantum wells.

In some embodiments, the apparatus may further include a first gate electrode configured to apply an electrical voltage bias to the photodetection layer.

In some further embodiments, the top surface of the first gate electrode may include a mirror configured to reflect at least a portion of the incident source to the photodetection layer.

In some further embodiments, a dielectric layer may be positioned between the voltage source and the first gate electrode, and the voltage drain and the first gate electrode.

In some still further embodiments, the photodetection layer may be suspended above the mirror by a separation distance, and wherein the photodetection layer may be substantially parallel with respect to the mirror.

In some further embodiments, the separation distance ranges between approximately 0.1-10 micron.

In other embodiments, the photodetection layer may include one or more nanostructures configured to extend from a first end of the photodetection layer to a second end of the photodetection layer.

In some embodiments, the one or more nanostructures may each define a nanostructure width and may be separated by a nanostructure separation distance.

In some embodiments, the apparatus may further include a second gate electrode configured to apply an electrical voltage bias to the photodetection layer either in addition to or in lieu of the electrical voltage bias applied by the first gate electrode.

In some further embodiments, the photodetection layer may be positioned between the first gate electrode and the second gate electrode.

In other embodiments, the source electrode and drain electrode may be positioned between the second gate electrode and the photodetection layer.

In some embodiments, the bottom surface of second gate electrode may include a dielectric layer such that the second gate electrode is electrically isolated from the voltage source and voltage drain.

In some embodiments, the photodetection layer may be positioned between a top dielectric layer and a bottom dielectric layer.

In some embodiments, the dielectric layer may include one or more of boron nitride, silicon oxide, silicon nitride, aluminum oxide, or hafnium oxide.

In some embodiments, the photodetection layer may be positioned between a top dielectric layer and a bottom dielectric layer.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will be appreciated that the scope of the disclosure encompasses many potential embodiments in addition to those here summarized, some of which will be further described below.

### BRIEF DESCRIPTION OF THE DRAWINGS

Having described certain example embodiments of the present disclosure in general terms above, reference will now be made to the accompanying drawings. The components illustrated in the figures may or may not be present in certain embodiments described herein. Some embodiments may include fewer (or more) components than those shown in the figures.

FIGS. 1A-1C illustrate an operational example of spectrum reconstruction using an example spectrometer and a photoresponse matrix, in accordance with some embodiments.

FIG. 2 illustrates a side profile view of an example four-terminal spectrometer configured with a voltage source, voltage drain, first gate electrode, and second gate electrode, in accordance with some embodiments.

FIGS. 3A-3D illustrates example characterizations of an example four-terminal spectrometer, in accordance with some embodiments.

FIGS. 4A-4B illustrate profile views of example three-terminal spectrometers configured with a voltage source, a voltage drain, and a first gate electrode, in accordance with some embodiments.

FIG. 5 illustrates an example of tunable absorption spectra of the example three-terminal spectrometer of FIG. 4A or FIG. 4B, in accordance with some embodiments.

FIG. 6 illustrates a profile view of an example three-terminal spectrometer with a photodetection layer configured with one or more nanostructures, in accordance with some embodiments.

FIG. 7 illustrates an example of tunable absorption spectra of the example three-terminal spectrometer of FIG. 6, in accordance with some embodiments.

FIG. 8 illustrates a cross section view of an example two-terminal spectrometer configured with a voltage source and a voltage drain, in accordance with some embodiments.

FIG. 9 illustrates an operational example for training a photoresponse matrix, in accordance with some embodiments.

FIG. 10 illustrates an example characterization of photocurrent as a function of excitation blackbody source temperature and electric displacement applied on a given spectrometer for the training of a photoresponse matrix, in accordance with some embodiments.

FIG. 11 illustrates an example characterization of a photoresponse as a function of wavelength and electric displacement for a given spectrometer based on a photoresponse matrix, in accordance with some embodiments.

FIGS. 12A-12H illustrate example processes for reconstruction of an unknown spectra in accordance with some embodiments.

FIG. 13 illustrates an example comparison between measured photocurrent using a conventional spectrometer and photocurrent reconstructed using a photoresponse matrix, in accordance with some embodiments.

FIG. 14 illustrates an example comparison between a measured photoresponse spectra of two photodetectors using a conventional spectrometer and photoresponse reconstructed using a photoresponse matrix, in accordance with some embodiments.

FIG. 15 illustrates an example computing device configured to, in whole or in part, perform various operations described herein.

FIG. 16 is a flowchart illustrating a method for generating a reconstructed spectrum according to an example embodiment of the present disclosure.

### DETAILED DESCRIPTION

The present invention now will be described more fully hereinafter with reference to the accompanying drawings in which some but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout. As used herein, terms such as “front,” “rear”, “side,” “top,” etc. are used for explanatory purposes in the examples provided below to describe the relative position of certain components or portions of components.

In some embodiments, the terms “electrically connected” may be used to refer to an electrical path between two or more components or the potential for a conducting path to be established under certain conditions between two or more components. A conducting path may allow for the flow of current between the two or more electrically connected components. In other words, the terms electrically connected may refer to any instance in which electrical current may be transmitted or otherwise flow between components.

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements.

As mentioned above, traditional spectrometers include mechanically movable components, which often results in bulky devices with large device footprints. Advancements in fabrication techniques have allowed on-chip spectrometers with smaller device footprints to be manufactured and used in a variety of applications, such as sensing, surveillance, and/or spectral imaging. The resolution of such on-chip spectrometers, however, is limited by the number of photodetectors within the spectrometer. Currently, on-chip spectrometers rely on the incorporation of a large array of photodetection elements to capture different spectral components of an incident source in order to reconstruct the corresponding spectrum, thereby resulting in high manufacturing costs and increasing fabrication complexity and time.

Embodiments of the present disclosure provide an apparatus that may operate as an on-chip spectrometer. The spectrometer may include a photodetection layer, a voltage source, and a voltage drain. The photodetection may include one or more photodetection materials which may generate a photoresponse in response to an incident source (e.g., light). The voltage source and voltage drain may be electrically coupled to the photodetection layer and may be configured to measure a photoresponse generated by the photodetection layer. Furthermore, the spectrometer may be associated with a photoresponse matrix which is configured with values determined based at least in part the photoresponse of the photodetection layer generated in response to one or more applied electrical voltage biases. As such, example embodiments of the present disclosure allow for streamlined, cost-efficient, and small device footprint single-detector spectrometer for on-chip spectroscopy.

### Example Photoresponse Matrix Determination

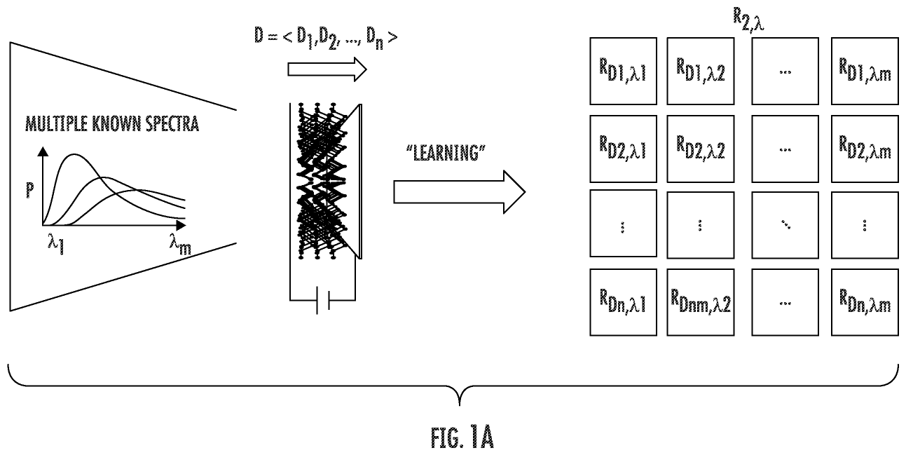

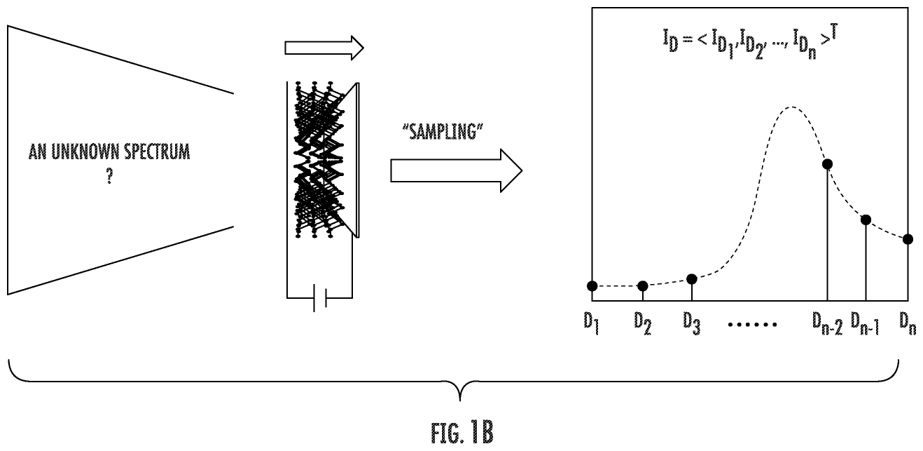

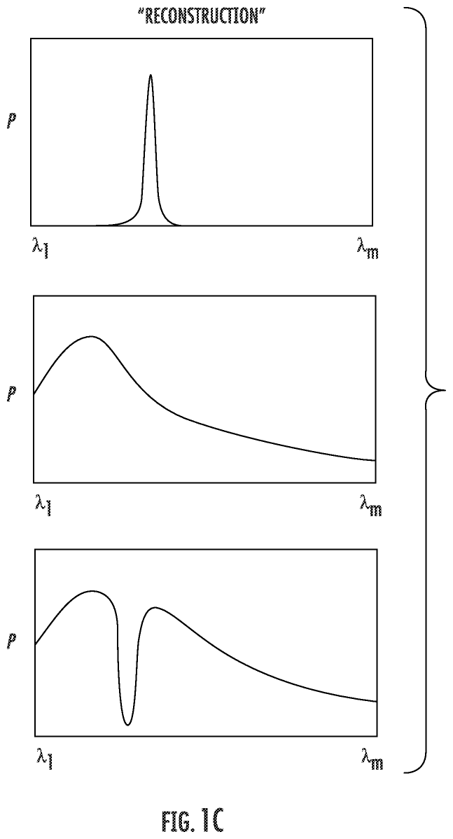

FIGS. 1A-1C depict an example operational scheme for using a spectrometer in accordance with example embodiments of the present disclosure to reconstruct a spectrum of an incident source, such as an unknown incident source. In general, the operation scheme for generating a reconstructed spectrum may include a learning step (e.g., training step), a sampling step, and a reconstruction step.

FIG. 1A depicts the operational scheme for an example learning step. During the learning step, the spectrometer photoresponse R may be determined as a function of displacement field D and wavelength λ. The optical properties of the photodetection layer may be tuned by an applied external biasing displacement field D, which may be controlled by applied voltages, as will be discussed hereafter. The photoresponse R of the photodetection layer may depend upon the photodetection layer for the particular spectrometer device (e.g., a thickness of the photodetection layer, selected photodetection materials, etc.). An example photoresponse matrix R_{Dλ} may be generated for the particular spectrometer.

During the learning step for a particular displacement field D (e.g., as controlled by an applied voltage), the photoresponse of the photodetection layer may be measured for multiple known incident spectra to generate a photoresponse row vector R_{Di}, where i is representative of the ith displacement field ranging between 1 and a maximum value of n. Each photoresponse row vector R_{Di} includes m photoresponse values R_{Di, λj} where j is representative of the jth wavelength ranging between 1 and a maximum value of m.

The photoresponse matrix R_{D, λ} may then be generated for the spectrometer based at least in part on photoresponse values R_{Di, λj} (e.g., as indicated by the corresponding photoresponse row vectors Dᵢ). As such, the photoresponse matrix R_{D, λ} may include one or more values based in part on the photoresponse of the photodetection layer generated in response to one or more applied electrical voltage biases. Thus, the photoresponse matrix R_{D, λ} provides for a means for calibration of the particular spectrometer.

FIG. 1B depicts the operational scheme for an example sampling step. During the sampling step, a measured photoresponse I (e.g., photocurrent) is measured for an unknown incident source of unknown spectrum. The photoresponse I may be measured for one or more displacement fields D, such as for each displacement field D, where i is representative of the ith displacement field ranging between 1 and a maximum value of n. A measured photoresponse vector I_{D} may be generated and include each measured photoresponse I_{Di}.

FIG. 1C depicts the operational scheme for an example reconstruction step. During the reconstruction step, one or more reconstructed spectra may be generated for the unknown incident source based at least in part on the photoresponse matrix R_{D, λ} for the device and the corresponding measured photoresponse vector I_{D} for the unknown source. In some embodiments, the transpose of the photoresponse vector I_{D} may be used during the reconstruction step.

In some embodiments, a blackbody incident source with tunable temperatures may be used to generate a photoresponse matrix as depicted in FIG. 9. In particular, learning data (e.g., photoresponse data) may be generated at one or more displacement fields D by a blackbody incident source at a temperature T. For a given displacement Dᵢ, a measured photoresponse (e.g., photocurrent) may be dependent upon the blackbody incident source temperature T and photoresponse R(λ), which is a function of wavelength λ. A measured photoresponse (e.g., photocurrent I) may be determined using the following formula:

$$I = f ( T , R ( λ ) ) \qquad Equation 1$$

Where ƒ is an unknown non-linear function, A regression analysis may be used to fit the non-linear relationship between the measured photoresponse I and temperature T and thus allow the photoresponse R(λ) to be inferred. The function ƒ may be mapped to the space of the incident source power density P(T, λ) and photoresponse R(λ). The incident source power density may be dependent upon the temperature T and wavelength λ of the blackbody incident source and thus, may be determined using Planck's Law.

The measured photoresponse (e.g., photocurrent I) may be represented as an integral of the product of the incident source power density and photoresponse over the entire wavelength range λᵢ, where i is between 1 to n. The measure photoresponse may be represented as:

$$I ( T ) = {\int }_{{λ}_{1}}^{{λ}_{n}} P ( T , λ ) R ( λ ) d λ \qquad Equation 2$$

In some embodiments, the temperature T may be a vector which includes all temperatures for which a measured photoresponse was generated. The temperature vector may include Tᵢ, where i ranges from 1 to m. For a given Tᵢ the measured photoresponse may be determined as:

$$I ( {T}_{i} ) = {\int }_{{λ}_{1}}^{{λ}_{n}} P ( {T}_{i} , λ ) R ( λ ) d λ \qquad Equation 3$$

For temperatures m temperatures, m integral equations may be determined and may be decomposed into an m-dimensional matrix equation by discretization to yield:

$$( {R}_{{λ}_{1}} , {R}_{{λ}_{2}} … {R}_{{λ}_{c}} ) ( \begin{matrix}{P}_{{T}_{1} , {λ}_{1}} & {P}_{{T}_{2} , {λ}_{1}} & … & {P}_{{T}_{m} , {λ}_{1}} \\ {P}_{{T}_{1} , {λ}_{2}} & {P}_{{T}_{2} , {λ}_{2}} & … & {P}_{{T}_{m} , {λ}_{2}} \\ ⋮ & ⋮ & ⋱ & ⋮ \\ {P}_{{T}_{1} , {λ}_{c}} & {P}_{{T}_{2} , {λ}_{c}} & … & {P}_{{T}_{m} , {λ}_{c}}\end{matrix} ) = ( {I}_{{T}_{1}} , {I}_{{T}_{2}} , … {I}_{{T}_{m}} ) \qquad Equation 4$$

The above equation may also be represented as R×P_{T}, λ=I_{T}. Equation 4 may allow for the photoresponse vector R_{Di} to be determined for a given displacement field Dᵢ. In some embodiments, the considered wavelengths λ_{c} may be selected to stabilize the solution against noise. Equation 4 may be solved using an adaptive Tikhonov regularization to generate the photoresponse matrix. In some embodiments, Equation 4 is solved using a least absolutely shrinkage and selection operator (LASSO) algorithm to generate the photoresponse matrix.

In some embodiments, Equation 4 may be approached using a generative adversarial network (GAN) machine learning model. The GAN model may be configured with a generator and discriminator. The generator may receive a random input, and then generate new spectra to meet Equation 4. The discriminator is trained to distinguish the generated spectra by the generator from real ones from a spectrum database of measured spectra. In the training of the generator and discriminator, the generator is trained to produce new spectra from random noise to fool the discriminator. In an instance the generated spectra capture the features of the spectrum database, the discriminator may provide an affirmative response to the generator. In an instance the generated spectra do not satisfies the criteria given by the discriminator, the discriminator may provide a rejection response. By properly training these two neural networks, the generator may learn the distribution of existing spectrum datasets, and generate spectra based on measured photoresponses. Although described herein with reference to a GAN used to solve Equation 4 to generate the photoresponse matrix, the present disclosure contemplates that any machine learning model or technique may be used based upon the intended application of the respective embodiment.

FIG. 9 depicts the determination of a photoresponse matrix using the incident source power density P(T, λ) and photoresponse R(λ). Plot 901 depicts incident source power densities P for three blackbody incident sources 901a-901c at temperatures Tᵢ, Tⱼ, and Tₖ, respectively, as well as an unknown photoresponse 901d for an unknown incident source as function of wavelength λ. The plot 902 further depicts that the photoresponse spectra (R×P) for each blackbody incident source at temperatures Tᵢ, Tⱼ, and Tₖ is determined by performing an integration of the photoresponse spectrum to determine a photoresponse (e.g., photocurrent). As shown in the inset of plot 902, the photoresponse (e.g., photocurrent) may be determined for a particular displacement field Dᵢ as a function of temperature. Furthermore, as shown in plot 903, a reconstructed spectrum may be determined for a certain displacement field Dᵢ based on the corresponding photoresponse (e.g., photocurrent) and/or incident source spectra as shown in plot 901 and/or 902. In some embodiments, the photoresponse matrix is represented as a series of photoresponse row vectors Dᵢ as shown in plot 903.

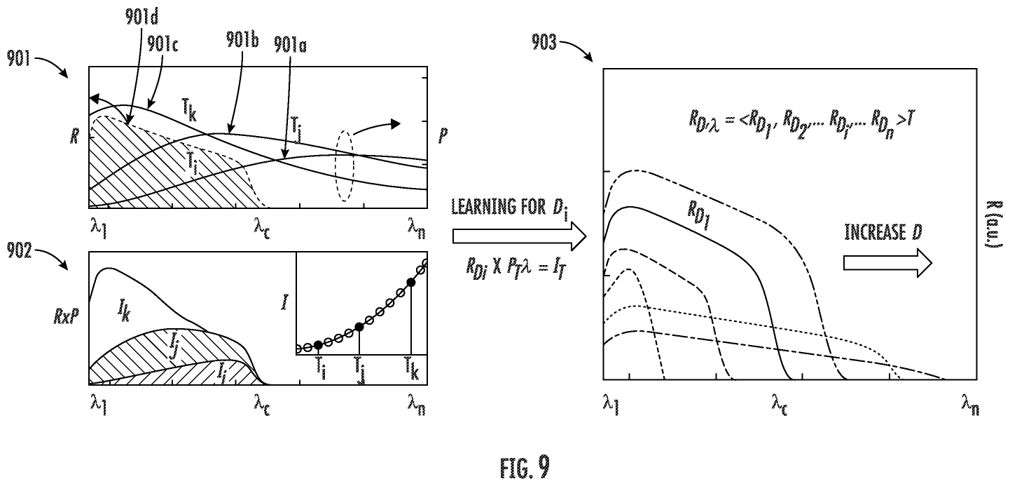

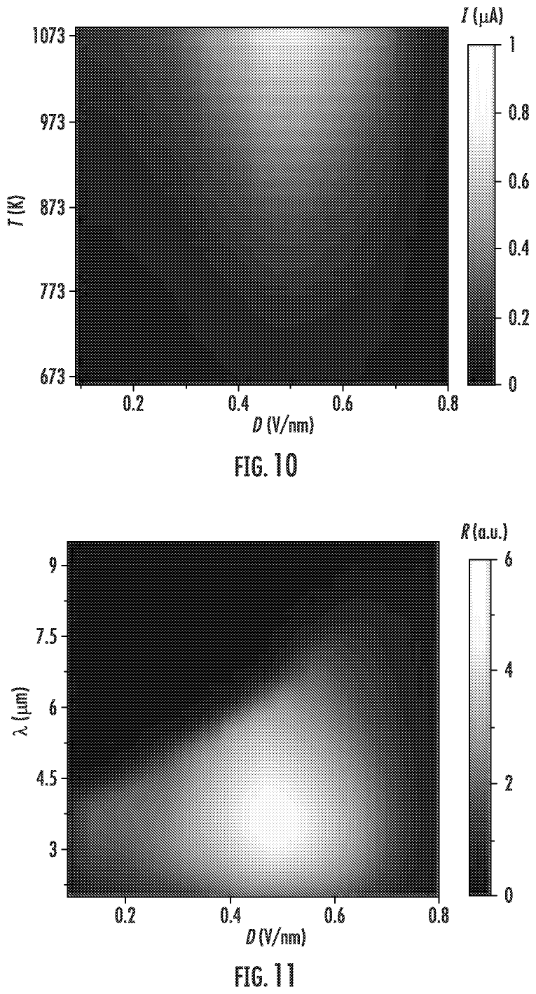

FIG. 10 depicts the measured photoresponse of an example spectrometer using 41 photoresponse row vectors as a function of the temperature of the blackbody incident source T and the displacement field D. FIG. 11 depicts an example photoresponse of an example spectrometer using 41 photoresponse row vectors as a function of the wavelength λ and the displacement field D.

Once the photoresponse matrix is determined, photoresponse measurements for unknown spectra may be measured and a reconstructed spectra may be determined based on the photoresponse measurements and the corresponding photoresponse matrix. In order to reconstruct unknown spectra, the photoresponse (e.g., photocurrent) may be measured as a function of a displacement field Dᵢ and the measured photoresponse I may be expressed as the following integral:

$$I ( {D}_{i} ) = {\int }_{{λ}_{1}}^{{λ}_{n}} R ( {D}_{i} , λ ) \times P ( λ ) d λ \qquad Equation 5$$

P(λ) may be the unknown spectra that is to be determined. In order to solve for a reconstruction vector, the continuous integral equation may be discretized and grouped into the following matrix equation:

$$( \begin{matrix}{R}_{{D}_{1} , {λ}_{1}} & {R}_{{D}_{1} , {λ}_{2}} & … & {R}_{{D}_{1} , {λ}_{n}} \\ {R}_{{D}_{2} , {λ}_{1}} & {R}_{{D}_{2} , {λ}_{2}} & … & {R}_{{D}_{2} , {λ}_{n}} \\ ⋮ & ⋮ & ⋱ & ⋮ \\ {R}_{{D}_{m} , {λ}_{1}} & {R}_{{D}_{m} , {λ}_{2}} & … & {R}_{{D}_{m} , {λ}_{n}}\end{matrix} ) ( \begin{matrix}{P}_{{λ}_{1}} \\ {P}_{{λ}_{2}} \\ ⋮ \\ {P}_{{λ}_{n}}\end{matrix} ) = ( \begin{matrix}{I}_{{D}_{1}} \\ {I}_{{D}_{2}} \\ ⋮ \\ {I}_{{D}_{m}}\end{matrix} ) \qquad Equation 6$$

Equation 6 may also be represented as R_{D, λ}×P=I_{D}. Equation 6 may be solved using an adaptive Tikhonov regularization algorithm. In some embodiments, Equation 6 is solved using a LASSO algorithm. In some embodiments, Equation 6 may be solved using convolutional neural network (CNN) machine learning algorithm. In some embodiments, Equation 6 may be solved using a generative adversarial network (GAN) machine learning model. The GAN machine learning model may be configured with a generator and discriminator. The generator may receive a random input, which it then provides to a discriminator. The discriminator may determine a loss function score for the received input, such as by using backpropagation, based on a spectrum database of measured spectra. In an instance the loss function score satisfies one or more loss function score thresholds, the discriminator may provide an affirmative response to the generator and the generator may reconstruct the spectra based at least in part on the provided input associated with the affirmative response. In an instance the loss function score does not satisfies the one or more loss function score thresholds, the discriminator may provide a rejection response to the generator and the generator may introduce noise into the previous input based at least in part on the loss function score. The generator may provide the updated input to the discriminator and repeat the process until the generator receives an affirmative response. Alternatively, a different neural network machine learning model may be used to solve Equation 6 to generate the photoresponse matrix.

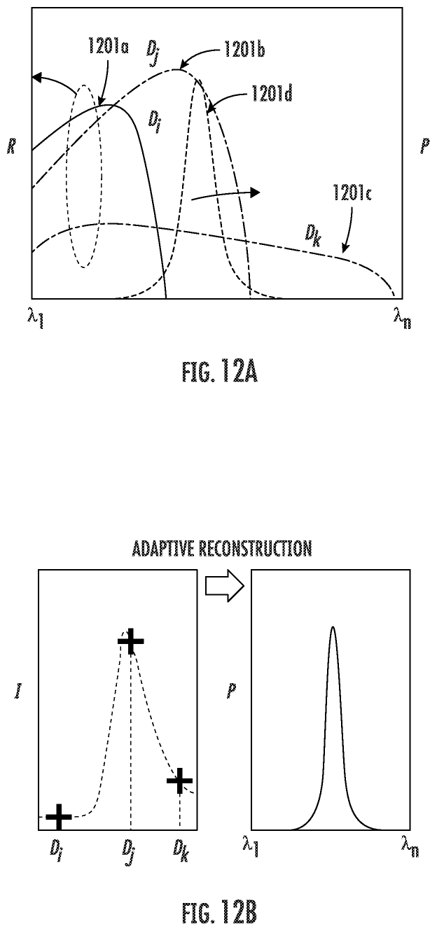

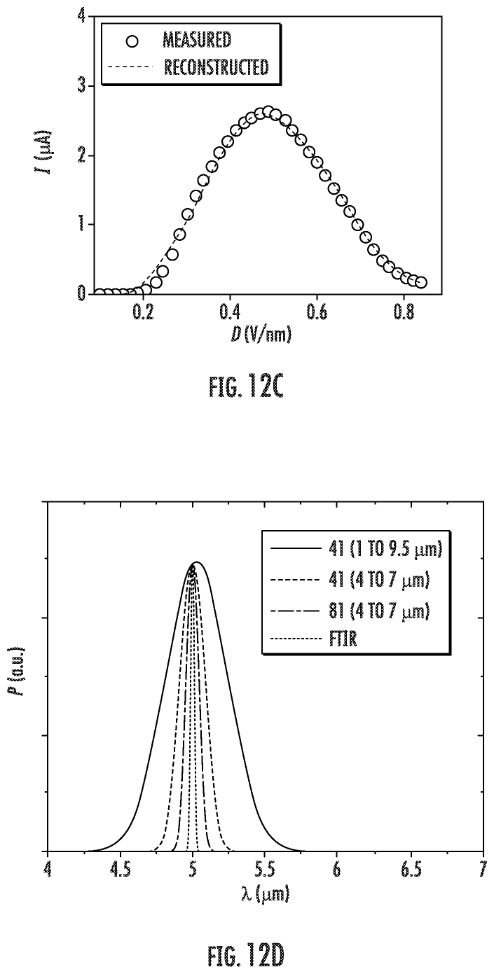

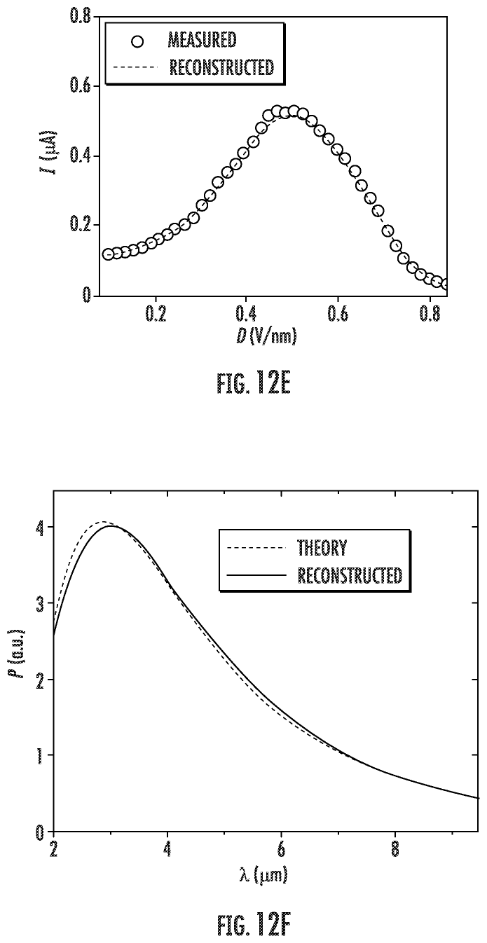

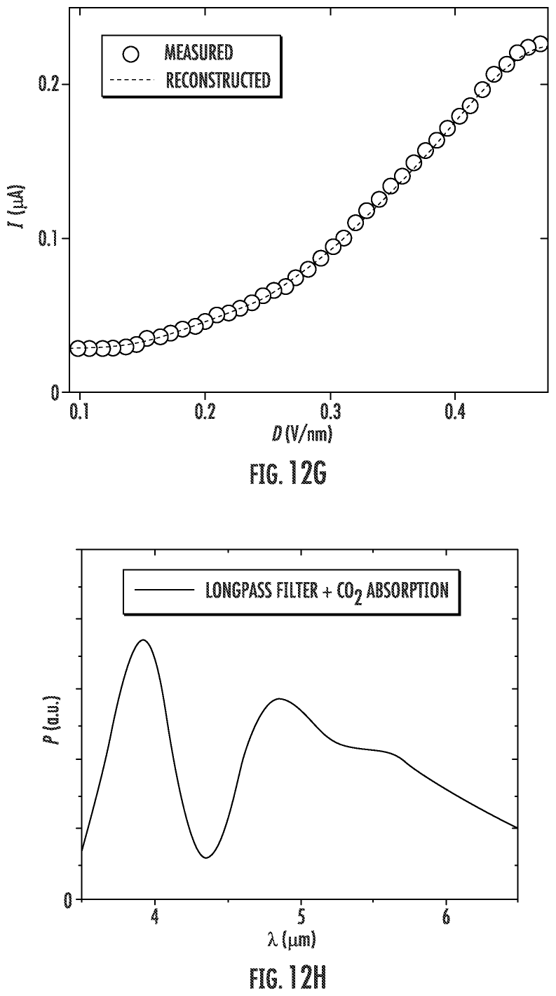

FIGS. 12A-12H depict an example process for reconstruction of an unknown spectra in accordance with some embodiments described herein. FIG. 12A depicts a photoresponse spectra 1201a-1201c at three displacement fields Dᵢ, Dⱼ, and Dₖ, respectively, and an unknown incident source spectra 1201d. FIG. 12B depicts the fitting the measured photoresponse (e.g., photocurrent) as a function of the displacement field D to reconstruct the unknown spectra. FIG. 12C depicts a measured photoresponse (e.g., photocurrent) generated in response to a 5-micrometer infrared laser incident source as a function of the displacement field D. The displacement field D may range from approximately 0.10 volts per nanometer (V/nm) to approximately 0.83 V/nm. A total of 41 measured photoresponses may be measured, resulting in 41 points plotted in the plot illustrated in FIG. 12C. FIG. 12D depicts a comparison of reconstructed spectra with one another and to a reference spectrum as measured by a FTIR. The reconstruction wavelength ranges may be between 1 to 9.5 micrometers with 41 points, 4 to 7 micrometers with 41 points, and 4 to 7 micrometers with 81 points. As illustrated in FIG. 12D, as the wavelength range is reduced and/or the number of sampling points is increased, the resolution of the spectrum is improved. FIG. 12E depicts a measured photoresponse (e.g., photocurrent) measured excited by a 1000 Kelvin blackbody incident source as a function of displacement field D. The dashed line represents the fitting in the corresponding reconstruction of the spectrum. FIG. 12F depicts the reconstructed spectrum for the measured blackbody incident source (e.g., as depicted in FIG. 12E) as well as the corresponding theoretical spectrum as determined by Planck's law (e.g., as shown by the dashed curve). As illustrated in FIG. 12F, the reconstructed curve agrees well with the theoretical curve. FIG. 12G depicts a measured photoresponse (e.g., photocurrent) measured displacement fields D ranging between 0.10 V/nm to 0.47 V/nm when a chamber within which the spectrometer is placed is filled with carbon dioxide (CO₂) and the photoresponse is measured using a long-pass filter cutoff at 3.7 micrometers in a conduction pathway. The dashed line represents the reconstructed spectra. FIG. 12H depicts the reconstructed spectrum from FIG. 12G. As shown in FIG. 12H, the carbon dioxide may absorb a portion of the incident source, which appears as a dip around 4.3 micrometers. This may be due to the infrared-active vibrational modes of carbon dioxide. The extinction edge (e.g., cutoff the long-pass filter is also shown around 3.7 micrometers.

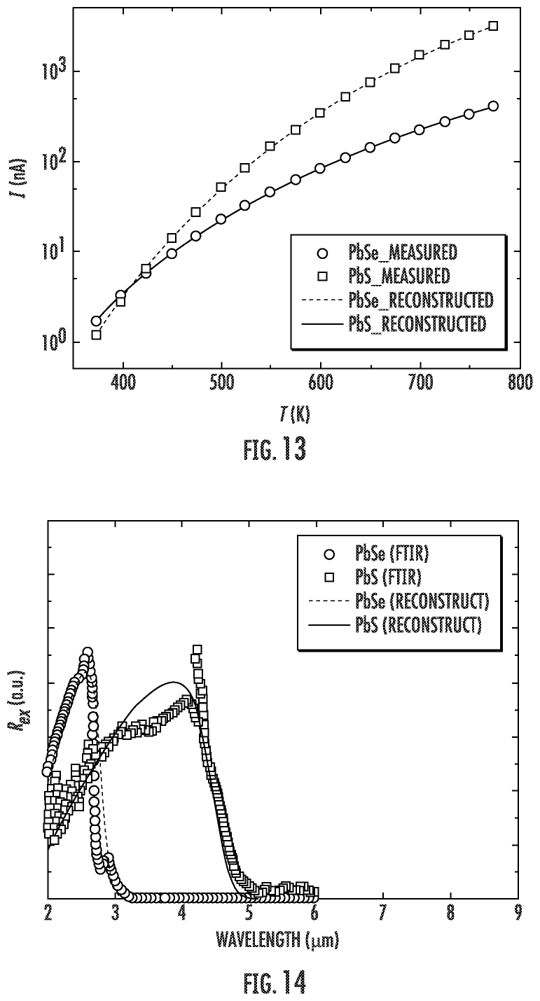

FIGS. 13 and 14 further illustrate the verification of the reconstructed spectra as compared to traditional methods. In particular, FIGS. 13-14 depict the measured photoresponse (e.g., photocurrent) of commercially available lead sulfide (PbS) and lead selenide (PbSe) photoconductors using the above-described methods as well as a standard FTIR method. FIG. 13 depicts crosses, representing the measured photoresponse as a function of temperature of the incident source. FIG. 14 depicts solid lines representing the spectra which were reconstructed using the photoresponse matrix, and the crosses represent the spectra measured directly using the FTIR spectrometer. As shown in FIGS. 13 and 14, the reconstructed spectra show consistent line shapes and cut-off wavelengths as compared to traditional FTIR spectrometers.

### Example Spectrometer Device

As described above, a spectrometer may be used to reconstruct spectra of an unknown source via the above-described operational scheme. In particular, a four-terminal spectrometer, three-terminal spectrometer, and/or two-terminal spectrometer may be used to reconstruct spectra in accordance with example embodiments of the present disclosure.

### Four-Terminal Spectrometer Device

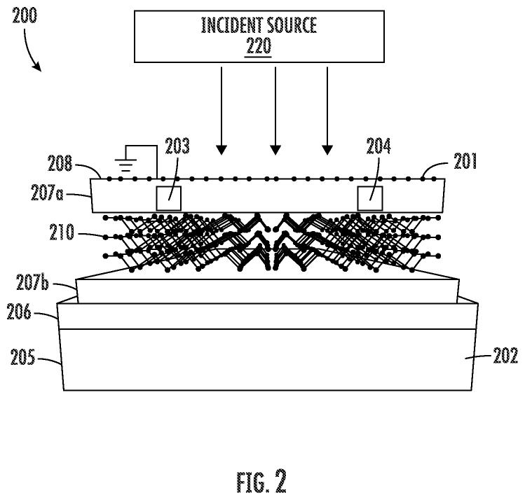

FIG. 2 depicts a side profile view of an example four-terminal spectrometer 200 in accordance with some embodiments. The spectrometer 200 may be configured with a voltage source 203, a voltage drain 204, a first gate electrode 202, and a second gate electrode 201. The spectrometer 200 may also be configured with a photodetection layer 210. The spectrometer 200 may be configured to generate a photoresponse using the photodetection layer 210 in response to an incident source 220.

The photodetection layer 210 may include one or more photodetection materials. The one or more photodetection materials may include one or more of narrow gap semiconductors, such as noble metal chalcogenides and/or elemental semiconductors. In particular, the one or more photodetection materials may include one or more of black phosphorous, palladium diselenide (PdSe₂), platinum diselenide (PtSe₂), tellurium (Te), arsenic (As), and/or phosphorous (P). Additionally or alternatively, the photodetection layer may include photodetection materials with a compositional form of AsₓP₁₋ₓ. In some embodiments, the photodetection layer may include photodetection materials with a compositional form SiₓGe_{y}Sn_{1-x-y} (silicon-germanium-tin) or GeₓSn₁₋ₓ (germanium tin). In some embodiments, the photodetection layer may include photodetection materials with a compositional form of MX₂, where M representative of an element which includes one of palladium (Pd), platinum (Pt), molybdenum (Mo), or tungsten (W), and X representative of an element which includes one of sulfur (S), selenium (Se), or tellurium (Te). In some embodiments, the photodetection layer may include photodetection materials with a compositional form of MX, where M representative of an element which includes one of germanium (Ge), indium (In), gallium (Ga) and X representative of an element which includes one of sulfur (S), selenium (Se), or tellurium (Te) or fractional combination of them. In some embodiments, the photodetection layer 210 may include photodetection materials with a compositional form M₂X₃, where M representative of an element which includes tin (Sn), indium (In), gallium (Ga) and X representative of an element which includes sulfur (S), selenium (Se), tellurium (Te) or fractional combination of them. In some embodiments, the photodetection layer 210 may be a thin film. For example, the photodetection layer 210 may have a thickness between approximately 5 nanometers and approximately 50 nanometers. In some embodiments, the photodetection layer 210 may have a thickness of approximately 13 nanometers. In some embodiments the photodetection layer 210 may comprise more than one material layer (for example, two sublayers WSe₂ and MoSe₂). In some embodiments, photodetection layer 210 may comprise one or more sublayers. The one or more sublayers may have a rotational angle between one or more adjacent sublayers.

The first gate electrode 202 and/or second gate electrode 201 may each generate an electrical voltage bias to the photodetection layer 210. The one or more electrical voltage biases may result in a displacement field D. The displacement field D may extend substantially perpendicular from the surface of the first gate electrode 202 and/or the surface of the second gate electrode 201. In the event a generated displacement field D is sufficient, an electrical connection variation (e.g., conduction of channel that represents the photoresponse) due to light excitation will be detected between the voltage source 203 and the voltage drain 204. The electrical voltage bias may be applied via direct current (DC) or alternating current (AC).

In some embodiments, the second gate electrode 201 may be composed of a thin layer of graphene. In some embodiments, the second gate electrode 201 is composed of a monolayer of graphene. In some embodiments, the first gate electrode 202 may be composed of silicon and/or silicon dioxide. In particular, the first gate electrode 202 may be composed of a silicon dioxide layer position on a top surface of a silicon substrate. In some embodiments, the second gate electrode 201 is composed of a thin layer of metal.

The voltage source 203 and voltage drain 204 may be composed of a conductive metal. In some embodiments, the voltage source 203 and voltage drain 204 are composed of either chromium or gold. The voltage source 203 and voltage drain 204 may be electrically connected to one another and the photodetection layer. As such, the voltage source 203 and voltage drain 204 may be configured to measure a photoresponse (e.g., a photocurrent) generated by the photodetection layer. The voltage source 203 and voltage drain 204 may be electrically isolated from the second gate electrode 201. In particular, an insulating layer 207a may electrically isolate the voltage source 203 and voltage drain 204 from the second gate electrode. In some embodiments, the insulating layer 207a may be composed of hexagonal boron nitride (hBN), silicon oxide, aluminum oxide, and/or hafnium oxide. The insulating layer 207a may be positioned between the second gate electrode 201 and a top surface of the photodetection layer 210. Furthermore, the insulating layer 207a may partially incorporate the voltage source 203 and voltage drain 204. However, as described above, the voltage source 203 and voltage drain 204 are electrically coupled to the photodetection layer 210. For example, the bottom surface of the voltage source 203 and voltage drain 204 may be in contact with the top layer of the photodetection layer 210.

In some embodiments, an insulating layer 207b may be positioned between a bottom surface of the photodetection layer 210 and the first gate electrode 202. In some embodiments, the insulating layer 207b may be composed of hexagonal boron nitride (hBN), silicon oxide, silicon nitride, aluminum oxide, and/or hafnium oxide, or other dielectrics. The insulating layers 207a and 207b may aid in the prevention of oxidation of the photodetection layer. Additionally, the insulating layers 207a and 207b may minimize trap-induced photocurrent when the photodetection layer generates a photoresponse. As such, the spectrometer 200 may operate in an intrinsic photoconduction or photovoltaic mode with negligible hysteresis.

The spectrometer 200 may be fabricated by the following fabrication process. A photodetection flake (e.g., a black phosphorous flake) of a desired thickness (e.g., 13 nanometers or the like) may be mechanically exfoliated and then encapsulated within two insulating flakes (e.g., hexagonal boron nitride flakes) in an argon filled glove box to form a heterostructure. The heterostructure may be transferred onto a substrate (e.g., silicon oxide of a particular thickness covered silicon substrate that serves as the first gate electrode). In some embodiments, the silicon oxide layer may be approximately 90 nanometers thick. The top insulating layer is then etched partially to expose the photodetection layer for contact metal deposition. The voltage source and voltage drain material (e.g., chromium and/or gold) may be thermally evaporated onto the exposed portion of the photodetection layer to form the voltage source, voltage drain, and contact pads for probing the device. In some embodiments, the voltage source and voltage drain may be approximately 30 nanometer thick, with approximately 3 nanometers of chromium and approximately 27 nanometers of gold. A third insulating layer is then transferred onto the exposed top layer of the voltage source and voltage drain. The material for the second gate electrode (e.g., graphene) may be generated using a chemical-vapor-deposition (CVD) techniques and then patterned onto the top surface of the top insulating layer using dry etch to isolate it from the voltage source and voltage drain.

The spectrometer 200 may then be characterized and/or used to reconstruct spectrum. To generate photoresponse characteristics, the spectrometer may be loaded into a low-temperature chamber at a particular temperature (e.g., 80 Kelvin or the like). The electrical bias voltage of the first electrode gate and second electrode gate may be measured using one or more source-meters. The photoresponse (e.g., photocurrent) generated by the photodetection layer is measured using the voltage source and voltage drain and by using a pre-amplifier and lock-in amplifier.

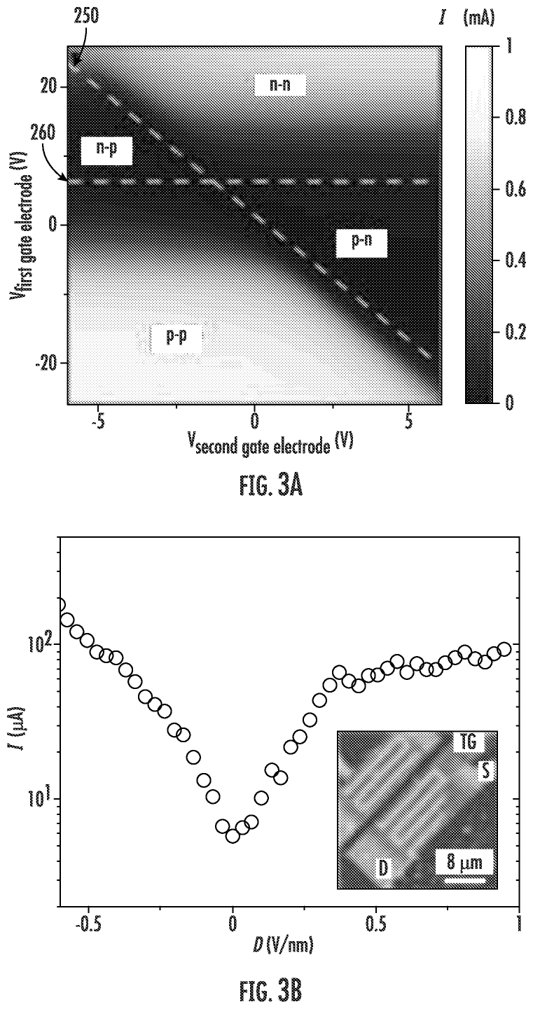

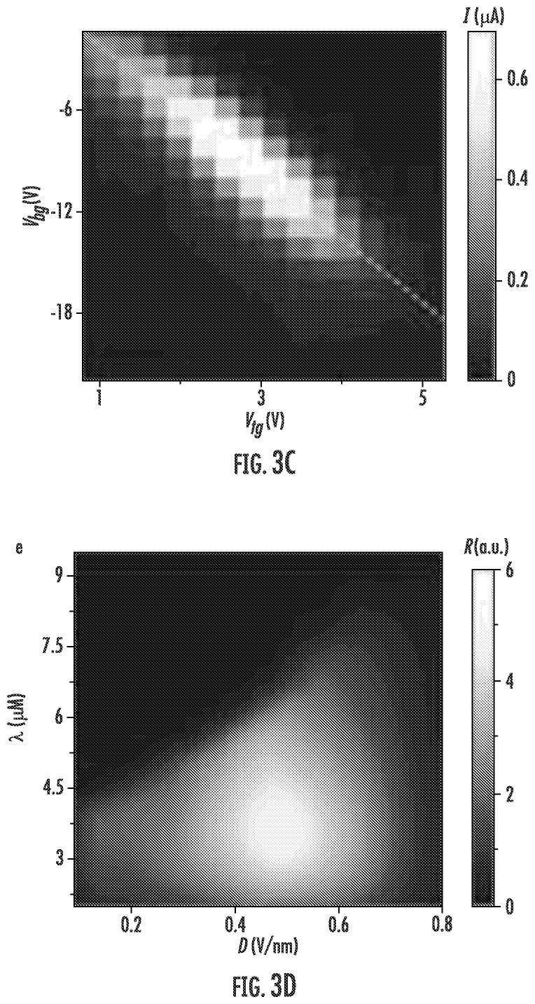

FIGS. 3A-3D depict various example characterizations of the example four-terminal spectrometer. In particular, FIG. 3A depicts a source-drain current as a function of applied electrical voltage biases from a second gate electrode 201 and first gate electrode 202. In this particular example, the current was determined while the spectrometer 200 was at 80 Kelvin, the voltage source 203 was grounded, and the voltage drain 204 was biased at 0.5 volts (V). The plotted photoresponse depicted in FIG. 3A may be divided into four regions, as illustrated by the dashed lines. The regions may be divided based on the polarities of the photodetection layer. For example, the line 250 may represent the charge neutrality condition of a conduction channel of the photodetection layer 210. The conduction channel of the photodetection layer 210 may be intrinsic to the photodetection layer due to the charge carriers within the photodetection layer being induced by both a top displacement field (e.g., caused by second gate electrode 201) and a bottom displacement field (e.g., caused by first gate electrode 202), thus having opposite polarities.

The line 260 may represent the conduction channel of the photodetection layer 210 directly under the voltage source 203 and voltage drain 204 due to the second gate electrode 201. Here, the photoresponse is intrinsic to the electrical voltage bias of the first gate electrode 202 regardless of the electrical voltage bias of the second gate electrode 201 due to the screening of the second gate electrode fields by the voltage source 203 and voltage drain 204.

FIG. 3B depicts the source-drain current as a function of the displacement field D along the charge neutrality line (e.g., line 250 as depicted in FIG. 3A). The displacement field D may be determined using the formula:

$$D = {ϵ}_{insulating layer} ( {V}_{first gate electrode} - {V}_{t 0} ) / {d}_{insulating layer} \qquad Equation 7$$

Here, ϵ_{insultating layer} and d_{insultating layer} are the permittivity of the insulating layer 207a and/or 207b and the thickness of the insulating layer 207a, respectively. In this particular example, hexagonal boron nitride was used as the insulating layer 207a and 207b such that ϵ_{insultating layer} is determined to be 3.1 and further, the insulating layer 207a was determined to have a thickness d_{insultating layer} of approximately 21 nanometers. The parameter Vₜ₀ may be a value to offset secondary gate electrode voltage to account for any doping of the photodetection layer 210. In this particular example, Vₜ₀ was determined to be approximately −0.7 volts. As shown in FIG. 3B, the photoresponse increases as the displacement field D increases, thus implying a reduction in the bandgap of the photodetection layer.

As depicted in FIG. 3C, a photoresponse (e.g., photocurrent I) is depicted as a function of electrical voltage bias of the first gate electrode 202 and second gate electrode 201. As shown in FIG. 3C, the maximum photoresponse was found to be along the charge condition line (e.g., line 250 in FIG. 3A), due to the charge carriers' lifetime being longest when a carrier density is minimized. As shown in FIG. 3C, photoresponse (e.g., photocurrent) increases when the electrical voltage bias increases due to photodetection layer absorption edge extending to a longer wavelength range when under an electrical voltage bias. However, once the electrical voltage bias of the second electrode gate exceeds an electrical bias voltage threshold value (or the corresponding displacement field D exceeds a displacement field threshold value), the photoresponse declines. For example, for an example four-terminal spectrometer exposed to a 1073 Kelvin blackbody incident source, the electrical bias voltage threshold value is 2.6 volts and/or a displacement field threshold value of 0.48 volts per nanometer. As such, when the second electrode gate exceeds am electrical bias voltage above 2.6 volts, a decline in photoresponse values may be seen. This may be due to the electrical bias voltage weakening oscillator strength and this, allowing less absorption by the photodetection layer. Additionally or alternatively, a reduction in bandgap in the photodetection layer may lead to higher intrinsic charge carrier concentration, which may reduce photocarrier lifetime.

FIG. 3D further depicts an example photoresponse matrix corresponding the four-terminal spectrometer 200. The photoresponse matrix is configured with values (e.g., photoresponse values R) as a function of wavelength λ and displacement field D that were determined during a learning step as described above. Each photoresponse value R corresponds to a particular wavelength λ and displacement field D. The photoresponse matrix may visually represent each photoresponse value R. A gradient photoresponse value scale may range from a minimum photoresponse value Rₘᵢₙ to a maximum photoresponse value Rₘₐₓ, where Rₘᵢₙ corresponds to a black value and Rₘₐₓ corresponds to a white value. Photoresponse values between Rₘᵢₙ and Rₘₐₓ may be a grayscale value between the black value (e.g., Rₘᵢₙ) and white value (e.g., Rₘₐₓ). Alternatively, the intermediary photoresponse values may have a color (e.g., red, orange, yellow) with a saturation value between the black value (e.g., Rₘᵢₙ) and white value (e.g., Rₘₐₓ).

### Three-Terminal Spectrometer Device

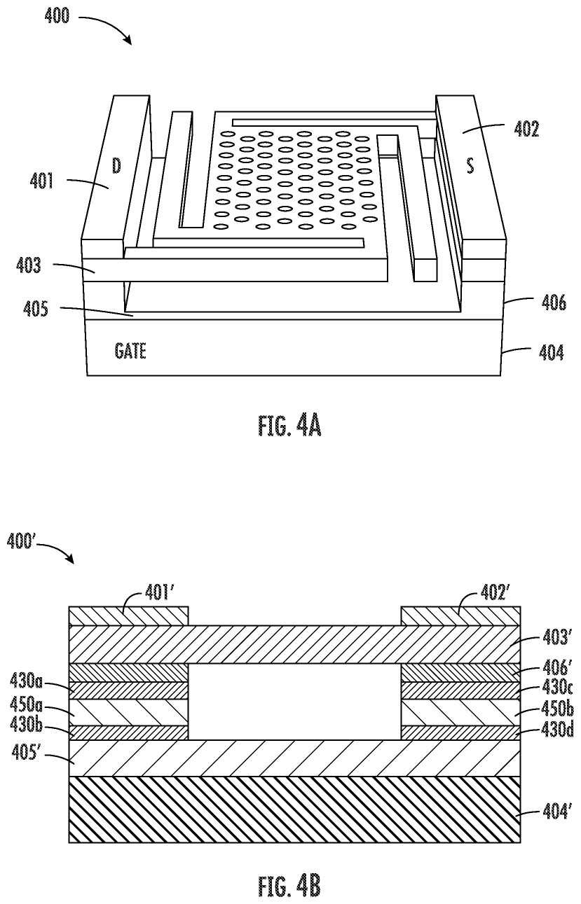

Referring now to FIG. 4A, a profile view of an example three-terminal spectrometer 400 is depicted in accordance with some embodiments. The spectrometer 400 may be configured with a voltage source 402, a voltage drain 401, and a first gate electrode 404. The top surface of the first gate electrode 404 may be a mirror 405. The spectrometer 400 may also be configured with a photodetection layer 403. The spectrometer 400 may be configured to generate a photoresponse using the photodetection layer 403 in response to an incident source. The three-terminal spectrometer 400 may be used with incident sources with spectrum in the visible and/or near-infrared spectral ranges.

In the spectrometer 400, the photodetection layer 403 may be suspended above the mirror 405 by a separation distance z and the photodetection layer 403 may be substantially parallel with respect to the mirror 405. The photodetection layer 403 may be a thin-film composed on a silicon, germanium, group III-group V material, and/or group II-VI material. Here, the photoresponse of the spectrometer 400 may be tuned based on the separation distance z between the photodetection layer 403 and the mirror 405. In some embodiments, the separation distance z may range between approximately 0.1 to 10 micrometers. The mirror 405 may be composed of gold such that it is a reflective surface. An incident source which impinges upon the mirror 405 may thus be reflect to the photodetection layer 403, which may generate a photoresponse.

The spectrometer may further include one or more insulating layers 406 between the first gate electrode 404 and the photodetection layer 403. In some embodiments, the first gate electrode 404 may be composed of silicon and/or silicon dioxide. In particular, the first gate electrode 404 may be composed of a silicon dioxide layer position on a top surface of a silicon substrate. In some embodiments, the insulating layer 406 may be composed of hexagonal boron nitride (hBN), silicon oxide, aluminum oxide, and/or hafnium oxide.

The voltage source 402 and voltage drain 401 may be composed of a conductive metal. In some embodiments, the voltage source 402 and voltage drain 401 are composed of either chromium or gold. The voltage source 402 and voltage drain 401 may be electrically connected to one another and the photodetection layer 403. As such, the voltage source 402 and voltage drain 401 may be configured to measure a photoresponse (e.g., absorption) generated by the photodetection layer 403.

The first gate electrode 404 may generate an electrical voltage bias, which may result in a displacement field D similarly as described with respect to FIG. 2. The functionality of the displacement field D in FIGS. 4A-4B is different. In the embodiments of FIG. 4A-4B, a change in the displacement field D changes the spacing between the photodetection layer 403 and the mirror 405, leading to the tuning of the spectral response. The electrical voltage bias may be applied in either direct current (DC) or alternating current (AC) mode.

In some embodiments, it may be desirable to control the separation distance z between the photodetection layer and the mirror as the photoresponse of the spectrometer may be tuned based on the separation distance z, such as via a micro-electric-mechanical system (MEMS). FIG. 4B illustrates an example three-terminal spectrometer 400′ configured with a voltage source 402′, a voltage drain 401′, and a first gate electrode 404′, as previously described with respect to FIG. 4A. Additionally, the top surface of the first gate electrode 404′ may be a mirror 405′ and the spectrometer 400′ may further include one or more insulating layers 406′ between the first gate electrode 404′ and the photodetection layer 403′. The spectrometer 400′ may also be configured with a photodetection layer 403′. The spectrometer 400′ may similarly be configured to generate a photoresponse using the photodetection layer 403′ in response to an incident source and may be used with incident sources with spectrum in the visible and/or near-infrared spectral ranges.

In addition to the above components, the spectrometer 400′ may be configured with piezoelectric layers 450a and 450b, which are positioned on opposite sides of the first mirror 405′ and are configured to support the photodetection layer 403′. The piezoelectric layers 450a and 450b may act as a micro-electric-mechanical system (MEMS) to effectively control the z between the photodetection layer 403′ and mirror 405′. Each piezoelectric layer may be positioned between two electrodes, which may be configured to apply an electrical voltage to the respective piezoelectric layer and induce mechanical shrinkage or expansion of the piezoelectric. In particular, electrodes 430a and 430b may control the mechanical change of piezoelectric layer 450a and electrodes 430c and 430d may control the mechanical change of piezoelectric layer 450b. The mechanical change induced in piezoelectric layers 450a and 450b may be substantially similar such that the photodetection layer 403 may remain substantially parallel with respect to the mirror 405. In some embodiments, the piezoelectric layers may be composed of any suitable piezeoelectric material, such as crystalline materials, ceramics, piezoceramic, type III-V semiconducting materials, type II-Vi semiconducting materials, polymers, and/or the like.

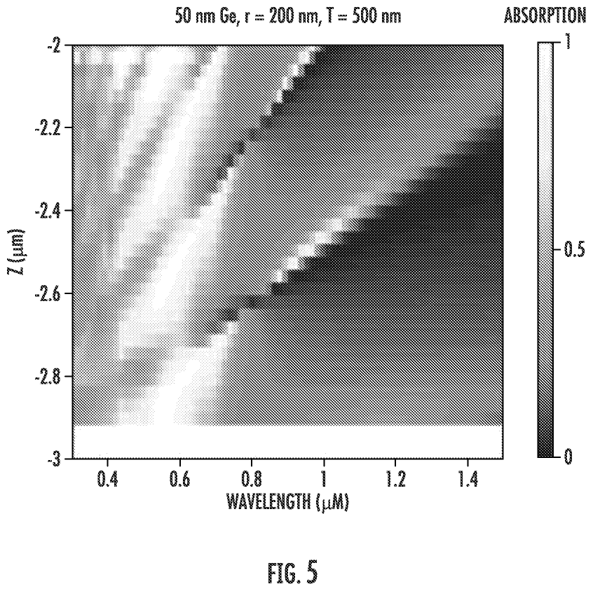

FIG. 5 depicts an example characterization of the example three-terminal spectrometer. In particular, an example photoresponse matrix corresponding to the three-terminal spectrometer 400 is depicted. The photoresponse matrix is configured with values (e.g., photoresponse values R) which are a function of wavelength λ and separation distance z between the photodetection layer 403 and the mirror 405 that were determined during a learning step as described above. Each photoresponse value R (e.g., absorption values) corresponds to a particular wavelength k and separation distance z. The photoresponse matrix may visually represent each photoresponse value R. A gradient photoresponse value scale may range from a minimum photoresponse value Rₘᵢₙ to a maximum photoresponse value Rₘₐₓ, where Rₘᵢₙ corresponds to a black value and Rₘₐₓ corresponds to a white value. Photoresponse values between Rₘᵢₙ and Rₘₐₓ may be a grayscale value between the black value (e.g., Rₘᵢₙ) and white value (e.g., Rₘₐₓ). Alternatively, the intermediary photoresponse values may have a color (e.g., red, orange, yellow) with a saturation value between the black value (e.g., Rₘᵢₙ) and white value (e.g., Rₘₐₓ). Here, the photoresponse value may correspond to an absorption value between 0 and 1, where absorption value of 0 is indicative that no incident source energy was absorbed by the photodetection layer and an absorption value of 1 is indicative that all the incident source energy was absorbed by the photodetection layer.

In some embodiments, the photodetection layer 403 may be configured with one or more nanostructures configured to extend from a first end of the photodetection layer to a second end of the photodetection layer. FIG. 6 depicts a spectrometer 400″ which includes a photodetection layer 403″ configured with one or more nanostructures. These nanostructures may improve the photoresponse of the photodetection layer. Each of the one or more nanostructures 403″a-403″e may define a nanostructure width W and may be separated from one another by a nanostructure separation distance S. Each nanostructure may further define a total nanostructure width T, which is the combination of the width of the nanostructure W and the separation distance S.

As described above with respect to FIG. 4A-4B, the photoresponse of the spectrometer 400′ may be tuned based on the separation distance x between the photodetection layer 403′ and the mirror 405. In some embodiments, the separation distance x may range between approximately 0.1 to 10 micrometers.

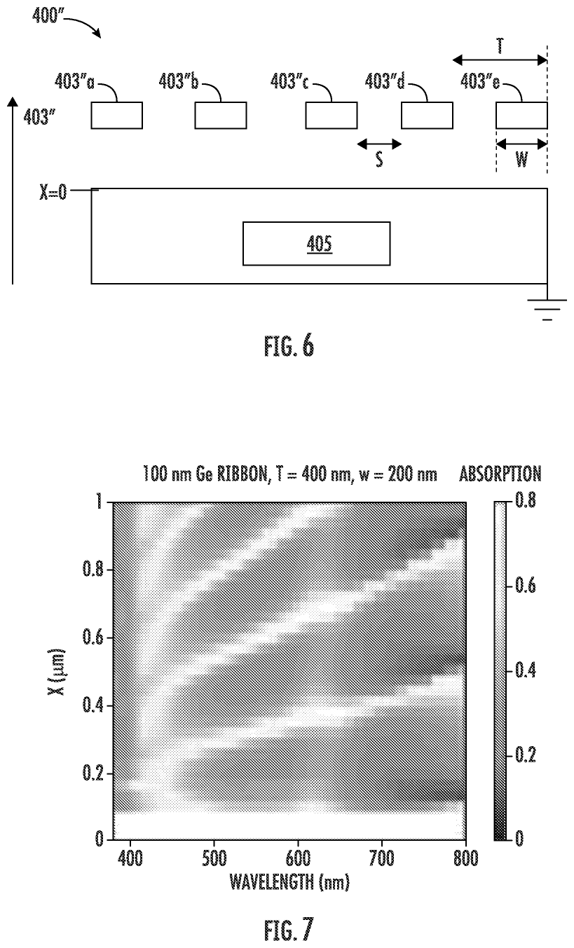

FIG. 7 depicts an example characterization of the example three-terminal spectrometer configured with a nanostructure photodetection layer. In particular, an example photoresponse matrix corresponding to the three-terminal spectrometer 400″ is depicted. The photoresponse matrix is configured with values (e.g., photoresponse values R) which are a function of wavelength λ and separation distance x between the photodetection layer 403″ (e.g., configured with one or more nanostructures) and the mirror 405 that were determined during a learning step as described above. Each photoresponse value R (e.g., absorption values) corresponds to a particular wavelength λ and separation distance x. The photoresponse matrix may visually represent each photoresponse value R. A gradient photoresponse value scale may range from a minimum photoresponse value Rₘᵢₙ to a maximum photoresponse value Rₘₐₓ, where Rₘᵢₙ corresponds to a black value and Rₘₐₓ corresponds to a white value. Photoresponse values between Rₘᵢₙ and Rₘₐₓ may be a grayscale value between the black value (e.g., Rₘᵢₙ) and white value (e.g., Rₘₐₓ). Alternatively, the intermediary photoresponse values may have a color (e.g., red, orange, yellow) with a saturation value between the black value (e.g., Rₘᵢₙ) and white value (e.g., Rₘₐₓ). Here, the photoresponse value may correspond to an absorption value between 0 and 1, where absorption value of 0 is indicative that no incident source energy was absorbed by the photodetection layer and an absorption value of 1 is indicative that all the incident source energy was absorbed by the photodetection layer.

### Two-Terminal Spectrometer Device

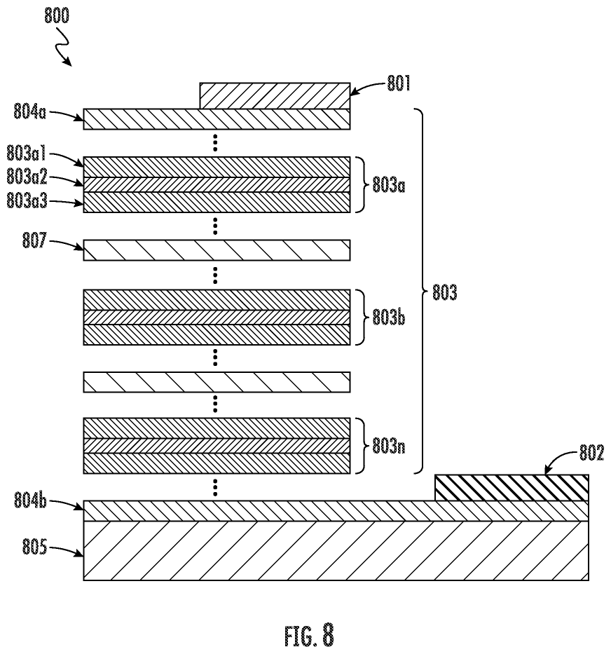

FIG. 8 depicts a side profile view of an example two-terminal spectrometer 800 in accordance with some embodiments. The spectrometer 800 may be configured with a voltage source 801 and voltage drain 802. The spectrometer 800 may also be configured with a photodetection layer 803. The spectrometer 800 may be configured to generate a photoresponse using the photodetection layer 803 in response to an incident source. The two-terminal spectrometer may be used for mid-infrared spectroscopy.

The photodetection layer 803 may define a plurality of quantum well structures. Each quantum well structure 803a-803n may be composed of a top barrier layer, a doped layer, and a bottom barrier layer. In some embodiments, each quantum well structure may further be composed of one or more connection layers. For example, the quantum well structure 803a may be composed of a top barrier layer 803al, a doped layer 803a2, and a bottom barrier layer 803a3. In some embodiments, the top barrier layer and/or bottom barrier layer may include a material with a compositional form of AlₓGa₁₋ₓAs (aluminum-gallium-arsenide). In some embodiments, the doped layer 803a2 may include a silicon doped gallium arsenide (GaAs) material. A connection layer 807 may also be composed of a silicon doped GaAs material. An interface connection layer 804a and/or 804b may be composed of a highly silicon doped GaAs material. The interface connection layer 804a may be positioned between a voltage source 801 and a first quantum well structure. The interface connection layer 804b may be positioned between an nth quantum well structure, where n is the total number of quantum wells defining the photodetection layer 803. In some embodiments, n may range between 2 to 10.

In some embodiments, the plurality of quantum well structures 803a-803n may be grown on a substrate 805. The substrate 805 may be composed on silicon, germanium, or a group III-group V material. The plurality of quantum well structures may be epitaxially grown from the substrate 805, such as by molecular beam epitaxy and/or chemical vapor deposition.

In some embodiments, the plurality of quantum well structures may be ordered according to opaqueness. That is, the quantum well structure which is the least opaque (e.g., most transparent) may be positioned at the top of the photodetection layer 803 (e.g., nearer to voltage source 801) while the most opaque (e.g., least transparent) quantum well structure may be positioned at the bottom of the photodetection layer 803 (e.g., nearer to the voltage drain 802). As such, an incident source may traverse through the plurality of quantum well structures in an order of increasing opaqueness. Furthermore, each quantum well structure may have a peak absorption wavelength, which may be based at least in part on the opaqueness of the quantum well structure.

The voltage source 801 and voltage drain 802 may be composed of a conductive metal. In some embodiments, the voltage source 801 and voltage drain 802 are composed of either chromium or gold. The voltage source 801 and voltage drain 802 may be electrically connected to one another and the photodetection layer 803. As such, the voltage source 801 and voltage drain 802 may be configured to measure a photoresponse (e.g., a photocurrent) generated by the photodetection layer 803. An electrical voltage bias may be applied between the voltage source 801 and voltage drain 802. The photoresponse of the spectrometer 800 may be tuned based on the nonlinear resistance and/or the strong Stark effect induced in the plurality of quantum well structures in the photodetection layer 803 induced by the electrical voltage bias. The electrical voltage bias may be applied in either direct current (DC) or alternating current (AC) mode.

Although not shown, similar to the photoresponse matrix depicted in FIGS. 3D, 5, and 7, a photoresponse matrix may be generated for the two-terminal spectrometer. The photoresponse matrix may be configured with values (e.g., photoresponse values R) as a function of wavelength λ and electrical voltage bias that were determined during a learning step as described above. The photoresponse matrix is configured with values (e.g., photoresponse values R) which are a function of wavelength λ and applied electrical voltage bias between the voltage source 801 and voltage drain 802 that were determined during a learning step as described above. Each photoresponse value R (e.g., absorption values) corresponds to a particular wavelength λ and applied electrical voltage bias. The photoresponse matrix may visually represent each photoresponse value R. A gradient photoresponse value scale may range from a minimum photoresponse value Rₘᵢₙ to a maximum photoresponse value Rₘₐₓ, where Rₘᵢₙ corresponds to a black value and Rₘₐₓ corresponds to a white value. Photoresponse values between Rₘᵢₙ and Rₘₐₓ may be a grayscale value between the black value (e.g., Rₘᵢₙ) and white value (e.g., Rₘₐₓ). Alternatively, the intermediary photoresponse values may have a color (e.g., red, orange, yellow) with a saturation value between the black value (e.g., Rₘᵢₙ) and white value (e.g., Rₘₐₓ). Here, the photoresponse value may correspond to an absorption value between 0 and 1, where absorption value of 0 is indicative that no incident source energy was absorbed by the photodetection layer and an absorption value of 1 is indicative that all the incident source energy was absorbed by the photodetection layer.

### Example Spectrum Reconstruction Method

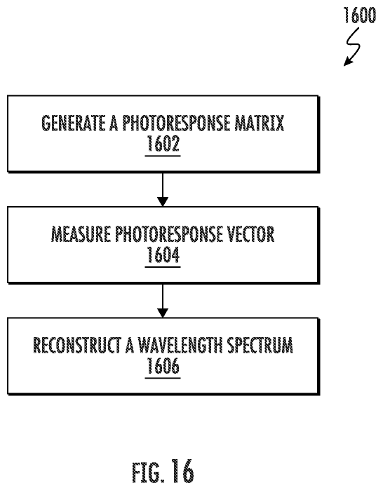

With reference to FIG. 16, a method of performing spectrum reconstruction according to embodiments of the invention is also provided (e.g., method 1600). A computing device 1500 may be configured to at least perform one or more operations, such as determining a photoresponse value, generating a photoresponse vector, determining a wavelength spectrum, generating a reconstructed wavelength spectrum, generating a photoresponse matrix, and/or the like as described above. As such and as shown at operation 1602, the computing device 1500 may include means, such as processor 202, communications circuitry 208, or the like, for generating a photoresponse of an apparatus (e.g., spectrometer). The photoresponse of the apparatus may be determined for one or more displacement fields D. In some embodiments, one or more intermediary computing devices, such as a source-meter, ammeter, and/or the like may be coupled to the spectrometer and further couple to the computing device 1500. Alternatively, the computing device 1500 may measure the photoresponse generated by the spectrometer indirectly (e.g., via manual input, output files generated by the one or more intermediary computing devices, and/or the like).

Thereafter, as shown at operation 1604, the computing device 1600 may include means such as processor 202, or the like, for generating a measured photoresponse vector. The measured photoresponse vector may include a photoresponse measured for each displacement field D.

Thereafter, as shown at operation 1606, the computing device 1600 may include means such as processor 202, or the like, for generating a reconstructed wavelength spectrum. The reconstructed wavelength spectrum may be based at least in part on the measured photoresponse vector and the photoresponse matrix corresponding to the apparatus. Values between two points indicated in the wavelength spectrum vector may be interpolated such that a continuous reconstructed wavelength spectrum is generated. The spectrum may be reconstructed using Equation 6, which may be solved using an adaptive Tikhonov regularization algorithm. In some embodiments, Equation 6 is solved using a LASSO algorithm.

In some embodiments, Equation 6 may be approached using a generative adversarial network (GAN) machine learning model. The GAN model may be configured with a generator and discriminator. The generator may receive a random input, which will then generate new spectra to meet Equation 6. The discriminator is trained to distinguish the generated spectra by the generator from real ones from a spectrum database of measured spectra. In the training of the generator and discriminator, the generator is trained to produce new spectra from random noise to fool the discriminator. In an instance the generated spectra capture the features of the spectrum database, the discriminator may provide an affirmative response to the generator. In an instance the generated spectra do not satisfies the criteria given by the discriminator, the discriminator may provide a rejection response. By properly training these two neural networks, the generator may learn the distribution of existing spectrum datasets, and generate spectra based on measured photoresponses. Although described herein with reference to a GAN used to solve Equation 4 to generate the photoresponse matrix, the present disclosure contemplates that any machine learning model or technique may be used based upon the intended application of the respective embodiment.

### Example Computing Entity

In some embodiments, a spectrometer, such as spectrometer 200, 400, 400′, or 800 may further comprise or otherwise be communicably coupled with a computing device 1500. The computing device 1500 may be configured to at least perform one or more operations, such as determining a photoresponse value, generating a photoresponse vector, determining a wavelength spectrum, generating a reconstructed wavelength spectrum, generating a photoresponse matrix, and/or the like as described above. One or more intermediary computing devices, such as a source-meter, ammeter, and/or the like may be coupled to the spectrometer and further couple to the computing device 1500. Alternatively, the computing device 1500 may receive information from the spectrometer and/or one or more intermediary computing devices indirectly (e.g., via manual input, output files generated by the one or more intermediary computing devices, and/or the like).

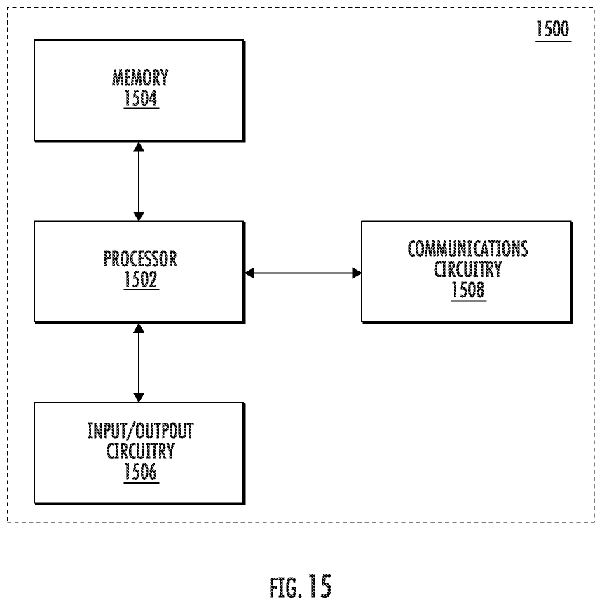

In order to perform these operations, the computing device 1500 may, as illustrated in FIG. 15, include a processor 1502, a memory 1504, input/output circuitry 1506, and/or communications circuitry 1508. The computing device 1500 may be configured to execute the operations described below in connection with FIGS. 1 and 9-16. Although components 1502-1508 are described in some cases using functional language, it should be understood that the particular implementations necessarily include use of particular hardware. It should also be understood that certain of these components 1502-1508 may include similar or common hardware. For example, two sets of circuitry may both use the same processor 1502, memory 1504, communications circuitry 1508, or the like to perform their associated functions, such that duplicate hardware is not required for each set of circuitry. The term “circuitry” as used herein includes particular hardware configured to perform the functions associated with respective circuitry described herein.

Of course, while the term “circuitry” should be understood broadly to include hardware, in some embodiments, the term “circuitry” may also include software for configuring the hardware. For example, although “circuitry” may include processing circuitry, storage media, network interfaces, input/output devices, and the like, other elements of the computing device 1500 may provide or supplement the functionality of particular circuitry.

In some embodiments, the processor 1502 (and/or co-processor or any other processing circuitry assisting or otherwise associated with the processor) may be in communication with the memory 1504 via a bus for passing information among components of the computing device 1500. The memory 1504 may be non-transitory and may include, for example, one or more volatile and/or non-volatile memories. In other words, for example, the memory may be an electronic storage device (e.g., a non-transitory computer readable storage medium). The memory 1504 may be configured to store information, data, content, applications, instructions, or the like, for enabling the computing device 1500 to carry out various functions in accordance with example embodiments of the present disclosure.

The processor 1502 may be embodied in a number of different ways and may, for example, include one or more processing devices configured to perform independently. Additionally or alternatively, the processor may include one or more processors configured in tandem via a bus to enable independent execution of instructions, pipelining, and/or multithreading. The use of the term “processing circuitry” may be understood to include a single core processor, a multi-core processor, multiple processors internal to the computing device, and/or remote or “cloud” processors.

In an example embodiment, the processor 1502 may be configured to execute instructions stored in the memory 1504 or otherwise accessible to the processor 1502. Alternatively or additionally, the processor 1502 may be configured to execute hard-coded functionality. As such, whether configured by hardware or by a combination of hardware with software, the processor 1502 may represent an entity (e.g., physically embodied in circuitry) capable of performing operations according to an embodiment of the present disclosure while configured accordingly. Alternatively, as another example, when the processor 1502 is embodied as an executor of software instructions, the instructions may specifically configure the processor 1502 to perform the algorithms and/or operations described herein when the instructions are executed.

The computing device 1500 further includes input/output circuitry 1506 that may, in turn, be in communication with processor 1502 to provide output to a user and to receive input from a user, user device, or another source. In this regard, the input/output circuitry 1506 may comprise a display that may be manipulated by a mobile application. In some embodiments, the input/output circuitry 1506 may also include additional functionality including a keyboard, a mouse, a joystick, a touch screen, touch areas, soft keys, a microphone, a speaker, or other input/output mechanisms. The processor 1502 and/or user interface circuitry comprising the processor 1502 may be configured to control one or more functions of a display through computer program instructions (e.g., software and/or firmware) stored on a memory accessible to the processor (e.g., memory 1504, and/or the like).

The communications circuitry 1508 may be any means such as a device or circuitry embodied in either hardware or a combination of hardware and software that is configured to receive and/or transmit data from/to a network and/or any other device, circuitry, or module in communication with the computing device 1500. In this regard, the communications circuitry 1508 may include, for example, a network interface for enabling communications with a wired or wireless communication network. For example, the communications circuitry 1508 may include one or more network interface cards, antennae, buses, switches, routers, modems, and supporting hardware and/or software, or any other device suitable for enabling communications via a network. Additionally or alternatively, the communication interface may include the circuitry for interacting with the antenna(s) to cause transmission of signals via the antenna(s) or to handle receipt of signals received via the antenna(s). These signals may be transmitted by the computing device 1500 using any of a number of wireless personal area network (PAN) technologies, such as Bluetooth® v1.0 through v3.0, Bluetooth Low Energy (BLE), infrared wireless (e.g., IrDA), ultra-wideband (UWB), induction wireless transmission, or the like. In addition, it should be understood that these signals may be transmitted using Wi-Fi, Near Field Communications (NFC), Worldwide Interoperability for Microwave Access (WiMAX) or other proximity-based communications protocols.

### Computer Program Products, Methods, and Computing Entities

Embodiments of the present invention may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language such as an assembly language associated with a particular hardware framework and/or operating system platform. A software component comprising assembly language instructions may require conversion into executable machine code by an assembler prior to execution by the hardware framework and/or platform. Another example programming language may be a higher-level programming language that may be portable across multiple frameworks. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid state card (SSC), solid state module (SSM), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present invention may also be implemented as methods, apparatuses, systems, computing devices, computing entities, and/or the like. As such, embodiments of the present invention may take the form of an apparatus, system, computing device, computing entity, and/or the like executing instructions stored on a computer-readable storage medium to perform certain steps or operations. Thus, embodiments of the present invention may also take the form of an entirely hardware embodiment, an entirely computer program product embodiment, and/or an embodiment that comprises combination of computer program products and hardware performing certain steps or operations.

Embodiments of the present invention are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatuses, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some exemplary embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

### CONCLUSION

Many modifications and other embodiments of the disclosure set forth herein will come to mind to one skilled in the art to which these embodiments pertain having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. An apparatus comprising:
a photodetection layer, wherein:
the photodetection layer comprises one or more photodetection materials, and
the photodetection layer is configured to generate a photoresponse in response to an incident source;
a voltage source electrically connected with the photodetection layer; and
a voltage drain electrically connected with the voltage source and the photodetection layer, wherein the voltage drain and the voltage source are configured to measure the photoresponse generated by the photodetection layer,
wherein a photoresponse matrix associated with the apparatus is configured with values determined based at least in part on the photoresponse of the photodetection layer generated in response to one or more applied electrical voltage biases to tune photodetection layer properties of the photodetection layer.

2. The apparatus of claim 1, wherein the voltage source and the voltage drain each comprise a conductive metal.

3. The apparatus of claim 1, further comprising:
a base substrate, wherein the voltage drain is positioned on a top side of the base substrate, the photodetection layer is positioned on a top side of the voltage drain, and the voltage source is positioned on a top side of the voltage source; and
a plurality of quantum well structures defined by the photodetection layer.

4. The apparatus of claim 3, wherein the plurality of quantum well structures further comprise a plurality of quantum well groups each of which is associated with a peak absorption wavelength.

5. The apparatus of claim 3, wherein the base substrate comprises a group III-group IV material, silicon, or germanium.

6. The apparatus of claim 3, wherein the base substrate is configured to epitaxially grow the plurality of quantum wells.

7. The apparatus of claim 1, the apparatus further comprising a first gate electrode configured to apply an electrical voltage bias to the photodetection layer.

8. The apparatus of claim 7, wherein a top surface of the first gate electrode comprises a mirror configured to reflect at least a portion of the incident source to the photodetection layer.

9. The apparatus of claim 7, wherein a dielectric layer is positioned between the voltage source and the first gate electrode and the voltage drain and the first gate electrode.

10. The apparatus of claim 8, wherein the photodetection layer is suspended above the mirror by a separation distance, and wherein the photodetection layer is substantially parallel with respect to the mirror.

11. The apparatus of claim 10, wherein the separation distance ranges between approximately 0.1-10 micron.

12. The apparatus of claim 7, wherein the photodetection layer comprises one or more nanostructures configured to extend from a first end of the photodetection layer to a second end of the photodetection layer.

13. The apparatus of claim 12, wherein the one or more nanostructures each define a nanostructure width and are separated by a nanostructure separation distance.

14. The apparatus of claim 7, further comprising a second gate electrode configured to apply an electrical voltage bias to the photodetection layer either in addition to or in lieu of the electrical voltage bias applied by the first gate electrode.

15. The apparatus of claim 14, wherein the photodetection layer is positioned between the first gate electrode and the second gate electrode.

16. The apparatus of claim 15, wherein the voltage source and voltage drain are positioned between the second gate electrode and the photodetection layer.

17. The apparatus of claim 14, wherein a bottom surface of the second gate electrode comprises a dielectric layer such that the second gate electrode is electrically isolated from the voltage source and voltage drain.

18. The apparatus of claim 14, wherein the photodetection layer is positioned between a top dielectric layer and a bottom dielectric layer.

19. The apparatus of claim 18, wherein each of the top dielectric layer and the bottom dielectric layer comprises one or more of boron nitride, silicon oxide, silicon nitride, aluminum oxide, or hafnium oxide.

20. The apparatus of claim 14, wherein the photodetection layer is positioned between a top dielectric layer and a bottom dielectric layer.
